(19) United States
(12) Patent Application Publication
(10) Pub. No.: US 2024/0006403 A1
(43) Pub. Date: Jan. 4, 2024

(54) HIGH-POWER ELECTRONICS DEVICES AND METHODS FOR MANUFACTURING SAME

(71) Applicant: Molex, LLC, Lisle, IL (US)

(72) Inventors: Victor Zaderej, Oregon, IL (US); Richard Fitzpatrick, Chicago, IL (US); Alan Han, Aurora, IL (US); Lily Yeung, Naperville, IL (US); Ronald C. Hodge, Montgomery, IL (US); Gary Thomas O'Connor, Bolingbrook, IL (US)

(21) Appl. No.: 18/036,904

(22) PCT Filed: Dec. 3, 2021
(86) PCT No.: PCT/IB2021/061333

§ 371 Date: May 15, 2023

Related U.S. Application Data
(60) Provisional application No. 63/121,524, filed on Dec. 4, 2020.

(51) Int. Cl. H01L 25/00; H01L 21/48; H01L 23/495; H01L 25/07; H05K 1/18; H01L 23/498; H05K 3/32; H05K 3/34

(52) U.S. Cl. CPC H01L 25/50; H01L 21/4842; H01L 23/49575; H01L 25/072; H01L 21/4846; H01L 23/49562; H05K 1/181; H01L 23/49861; H05K 3/32; H05K 3/3426; H05K 2201/10166; H05K 2201/1053; H05K 2201/10522; H05K 2201/10818; H05K 2201/10378; H05K 2201/10628

(57) ABSTRACT

A high-power electronics device and a method of forming same are disclosed. The high-power electronics device is formed of a plurality of layers including molding compound, a printed circuit board, electrically conductive contacts, at least one electronic component, and molding compound. In an embodiment, a layer of a dielectric carrier is also provided.

### RELATED APPLICATIONS

This application claims priority to U.S. Provisional Application No. 63/121,524 filed Dec. 4, 2020, which is incorporated herein by reference.

### FIELD OF THE DISCLOSURE

The present disclosure is directed to high-power electronics devices and methods of manufacturing same. More specifically, this disclosure relates to solid-state devices and methods of manufacturing same.

### DESCRIPTION OF RELATED ART

As the “moving vehicle,” industrial, commercial, and consumer markets become electrified, the need for more reliable, smaller, lighter weight, and lower cost electronics grows. Along with this trend, there is a need for controls and switches that will be used to reliably and intelligently regulate the electrics.

In the past, relays were used to provide this function, but relays are large, electro-mechanical devices with limited life and performance, unable to meet growing requirements. Relays are not a practical alternative for next generation electronics.

Solid-state switches which use MOSFETs (Metal Oxide Field Effect Transistors) are a more reliable, smaller, lighter, and cost-effective alternatives to the relays that have been used in the past. MOSFETs can be used individually or be placed in parallel to carry several hundred amps of current for the applications that require this level of power.

One of the challenges associated with transferring high power (high current) is the heat generated in the current path (I²×R). As the heat increases, the life and performance of the electronics is reduced. The key to minimizing the heat generated in the current path is to reduce the resistance in the system.

With conventional printed circuit board (PCB) packaging methods, the ability to carry high current is limited by the thickness of the copper traces. For higher current applications, the practical limit due to the processes used to manufacture PCBs, are circuit boards with four (4) ounce (144 micron thick) copper layers. In some cases, multiple layers are interconnected with electrical and thermal vias in order to be able to carry higher current and to remove heat. This causes a number of problems: PCBs get very expensive; heat becomes difficult to remove from inner layers; and mixing high current layers with signal layers gets to be very challenging.

Applicant has a proprietary technology—referred to as ASEP technology—which integrates the benefits of high current conductive metal stampings, high temperature dielectric materials, and selectively metalized circuit patterns on the surface of the dielectric materials to create a system that is often smaller, lighter, more reliable, and cost effective. ASEP technology allows designers to create high current carrying switches or modules using conventional manufacturing methods such as stamping and molding, eliminating the need for expensive (thick copper) PCBs, reducing the size of the system, and ultimately producing a very cost-effective product.

Although ASEP technology enables the design and manufacture of high-power electronics devices that may not have been possible in the past, the process requires additional capital and tooling. For lower volume applications, the additional costs may be difficult to justify. Furthermore, there may be some applications that could be produced using more conventional manufacturing methods.

Thus, there is a need for improved high-power electronics devices and improved methods of manufacturing same.

### BRIEF SUMMARY

Accordingly, in an embodiment, the present disclosure provides a high-power electronics device formed of a first layer of molding compound, a second layer on top of the first layer comprising a printed circuit board, a third layer on top of the second layer formed of electrically conductive contacts, a fourth layer on top of the third layer formed of at least one electronic component, and a fifth layer on top of the fourth layer formed of molding compound.

In an embodiment, the present disclosure provides a high-power electronics device formed of a first layer of molding compound, a second layer on top of the first layer comprising a printed circuit board, a third layer on top of the second layer formed of electrically conductive contacts, a fourth layer on top of the third layer formed of at least one electronic component, and a fifth layer on top of the fourth layer formed of molding compound.

In an embodiment, the present disclosure provides a method of forming a high-power electronics device including forming a stamping out of a sheet of thick conductive material, the stamping including a lead frame portion and at least first and second electronic component mounting contacts coupled to the lead frame portion by fingers, and attaching an electronic component to the first and second electronic component mounting contacts to form an assembly, the electronic component having a plurality of terminals, wherein one of the plurality of terminals of the electronic component is not attached to the first and second electronic component mounting contacts.

### BRIEF DESCRIPTION OF THE DRAWINGS

The present disclosure is illustrated by way of example, and not limited, in the accompanying figures in which like reference numerals indicate similar elements and in which:

FIG. 1 depicts a perspective view of a high-power electronics device;

FIGS. 2-10 illustrate top plan views of components used in a first method of forming the high-power electronics device; and

FIGS. 11-16 illustrate top plan views of components used in a second method of forming the high-power electronics device.

### DETAILED DESCRIPTION

The appended drawings illustrate embodiments of the present disclosure and it is to be understood that the disclosed embodiments are merely exemplary of the disclosure, which may be embodied in various forms. Therefore, specific details disclosed herein are not to be interpreted as limiting, but merely as a basis for the claims and as a representative basis for teaching one skilled in the art to variously employ the present disclosure.

A high-power electronics device 20 and improved methods of manufacturing same are provided herein. One type of high-power electronics device 20 are solid-state devices, such as a solid-state switch which requires one FET (Field Effect Transistor) for switching less than 50 Amps of power. In an embodiment, the FET is a MOSFET (Metal Oxide Field Effect Transistors).

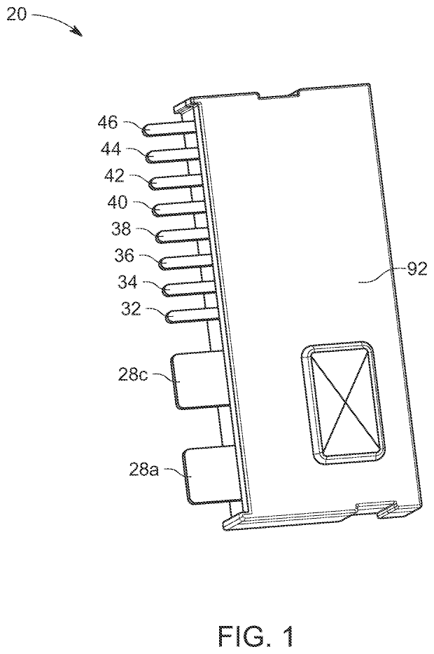

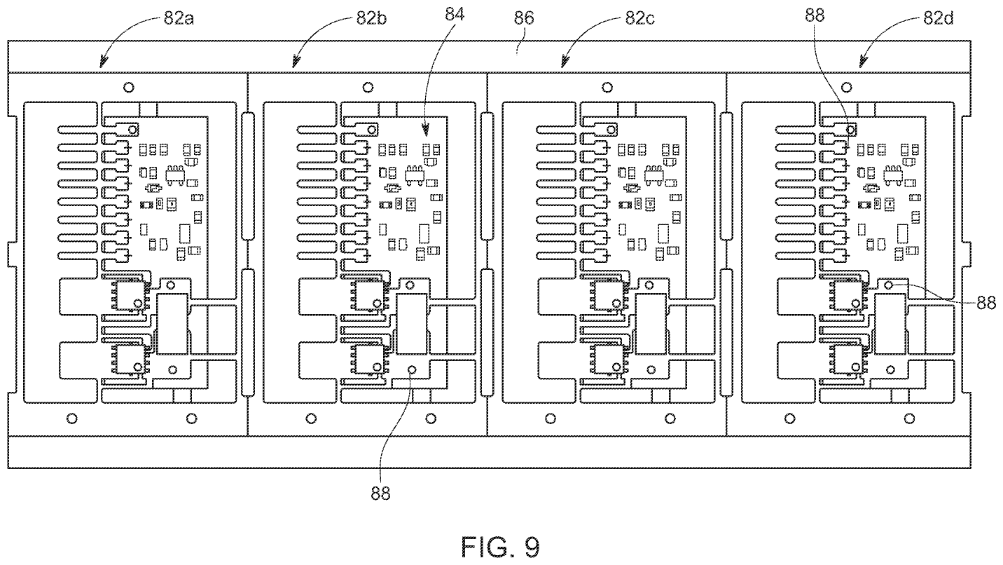

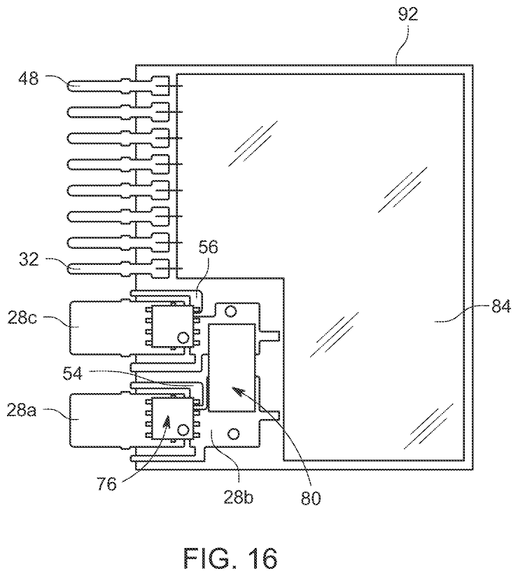

A first method of manufacturing is shown in FIGS. 1-10; and a second method of manufacturing is shown in FIGS. 1, 2 and 11-16.

Attention is invited to the first method of manufacturing shown in FIGS. 1-10 which is performed by the following steps.

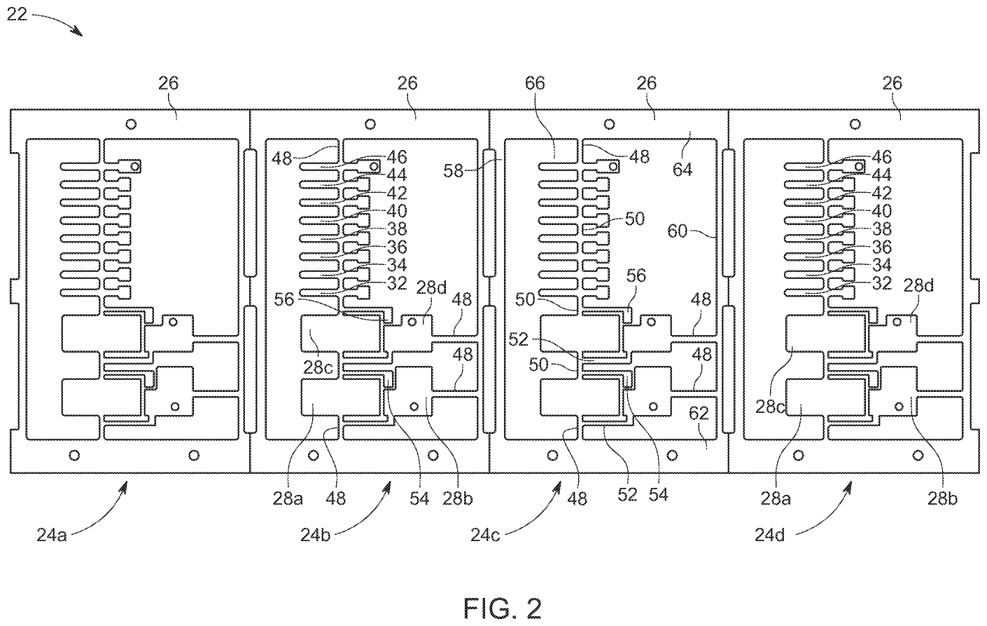

As shown in FIG. 2, a stamping 22 is formed of a sheet of thick conductive material. In an embodiment, the material is copper. In another embodiment, the material is aluminum. The material has a thickness of about 200 microns to about 3,000 microns, and preferably has a thickness of about 500 microns to about 800 microns, which is much thicker than conventional traces provided on current printed circuit boards as discussed hereinabove. Since the stamping 22 has a great thickness, the stamping 22 is capable of carrying high current without the need to stack multiple stampings on top of each other. The stamping 22 may be formed in a reel-to-reel (continuous flow) manufacturing process.

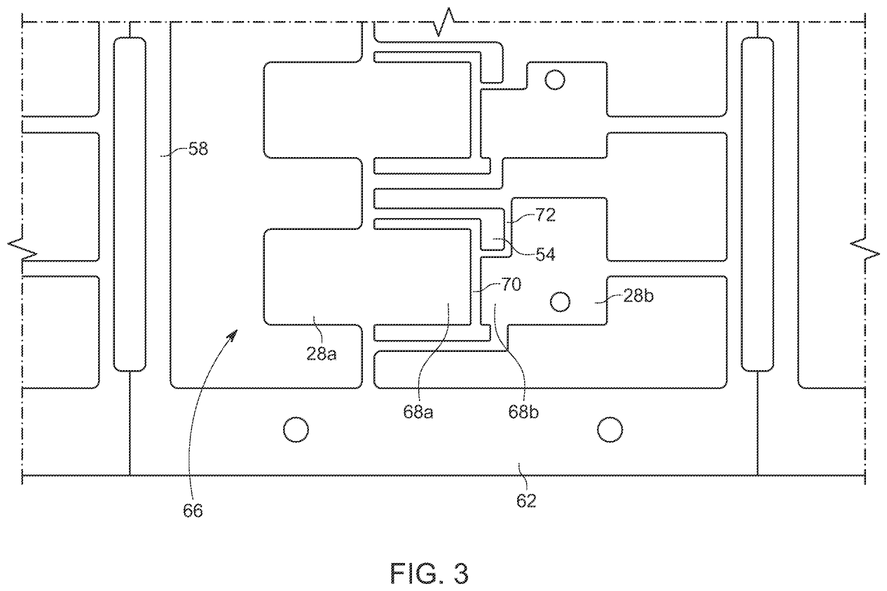

As shown in FIGS. 2 and 3, the stamping 22 includes a plurality of contact subassemblies 24a, 24b, 24c, 24d, each of which includes a lead frame section 26 and a plurality of contacts 28a, 28b, 28c, 28d and 32, 34, 36, 38, 40, 42, 44, 46, some of which are coupled to the lead frame section by lead frame connecting fingers 48 and some of which are connected to each other by contact connecting fingers 50. Finger connecting fingers 52 may be provided to connect contacts, such as contacts 28b, 28d to lead frame connecting fingers 48. Each contact subassembly 24a, 24b, 24c, 24d further includes a circuit board contact 54, 56 which may extend from one of the fingers 50 or may extend from the lead frame 26. In the embodiment as shown, each lead frame section 26 has first, second, third and fourth lead frame portions 58, 60, 62, 64 which define an interior space 66 in which the contacts and fingers are provided. If only three lead frame portions 58, 60, 62 are provided, the interior space 66 is further defined by the first lead frame portion 58 of the adjacent contact subassembly 24a, 24b, 24c, 24d. The first and second lead frame portions 58, 60 of the contact subassemblies 24a, 24b, 24c, 24d are parallel to each other, and the second and third lead frame portions 62, 64 of the contact subassemblies 24a, 24b, 24c, 24d are continuous with each other and perpendicular to the first and second lead frame portions 58, 60. The contacts of each contact subassembly 24a, 24b, 24c, 24d include at least first and second electronic component mounting contacts, shown as contacts 28a, 28b. As shown, other contacts extending from one of the lead frame sections 26 may also be provided.

The first electronic component mounting contact 28a has a first mounting portion 68a which is adjacent to, parallel to, and spaced from a second mounting portion 68b of the electronic component mounting contact 28b. A space 70 is defined between the first and second mounting portions 68a, 68b. One of the mounting portions 68a has a length which is greater than the length of the other mounting portion 68b such that a void 72 is provided. The circuit board contact 54 extends into the void 72. The configuration shown in FIGS. 2 and 3 represents an example of the contacts and fingers in the contact subassemblies, and other configurations are within the scope of the present disclosure.

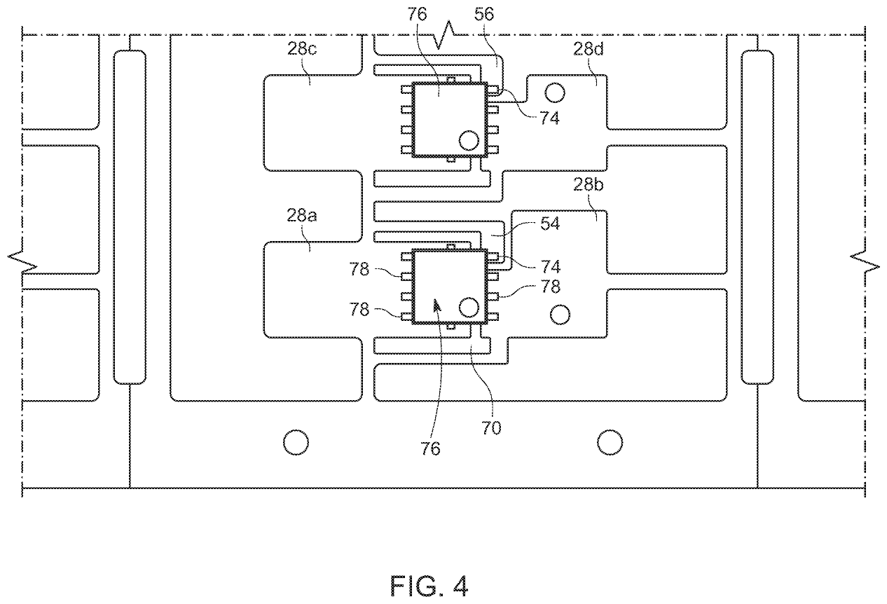

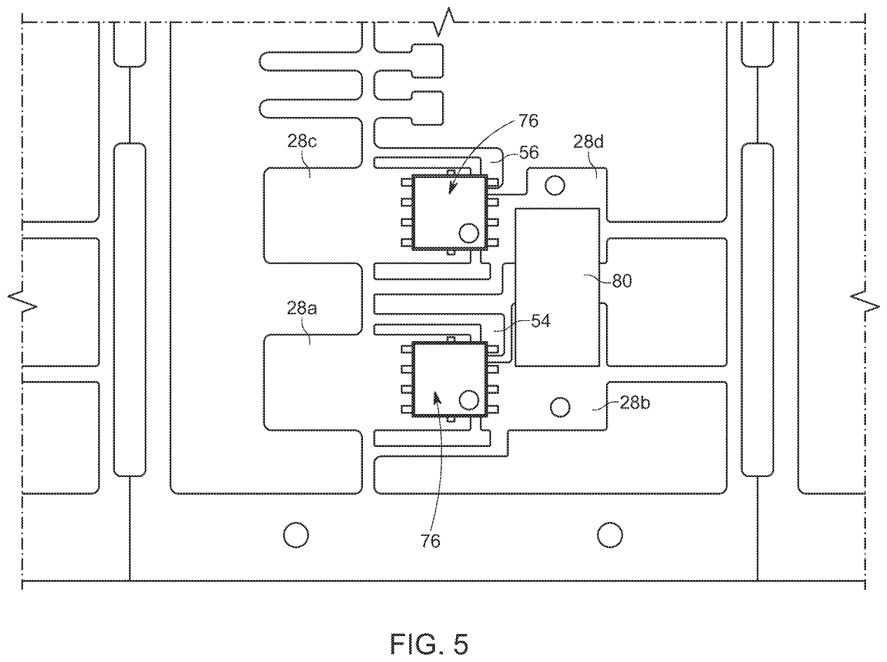

As shown in FIGS. 4 and 5, a signal terminal 74 of an electronic component 76, such as a FET, is electrically coupled, for example by solder, wire or ribbon bond, and the like, to the circuit board contact 54, and the remaining contacts 78 of the electronic component 76 are electrically coupled, for example by solder, wire or ribbon bond, and the like, to the first and second mounting portions 68a, 68b. The electronic component 76 straddles the space 70 between the first and second mounting portions 68a, 68b. Further, the electronic component mounting contacts 28c, 28d and the second circuit board contact 56 are formed as part of the stamping 22, and a second electronic component 76, such as a FET, is electrically coupled in the same manner. This configuration protects the resulting switch from being switched from the battery voltage being reversed. If reverse battery protection is not required, the second electronic component 76, the mounting contacts 28c, 28d, and the second circuit board contact 56 would not be necessary, but minor modifications would be required to complete the circuit, e.g., the addition of a zero Ohm resistor or strap, as would be understood by one of ordinary skill in the art. A shunt 80, see FIG. 5, may also be electrically coupled between the second electronic component mounting contacts 28b, 28d to allow for measurement of current flow.

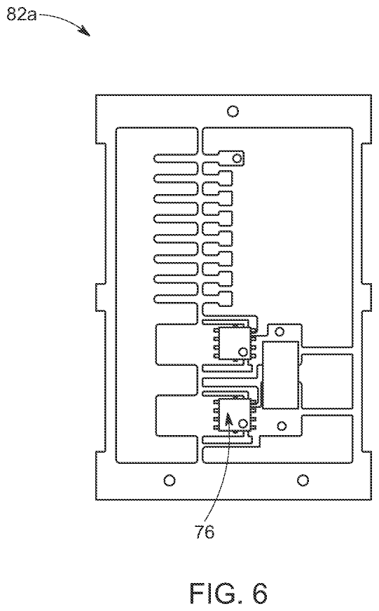

Thereafter, as shown in FIG. 6, the contact subassemblies 24a, 24b, 24c, 24d are singulated to form individual subassemblies 82a, 82b, 82c, 82d with the electronic component 76 mounted thereon.

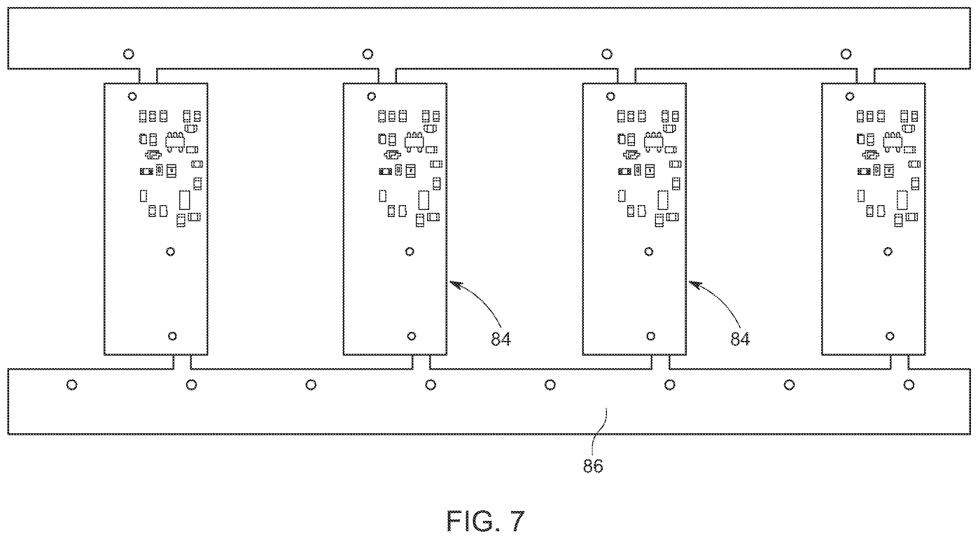

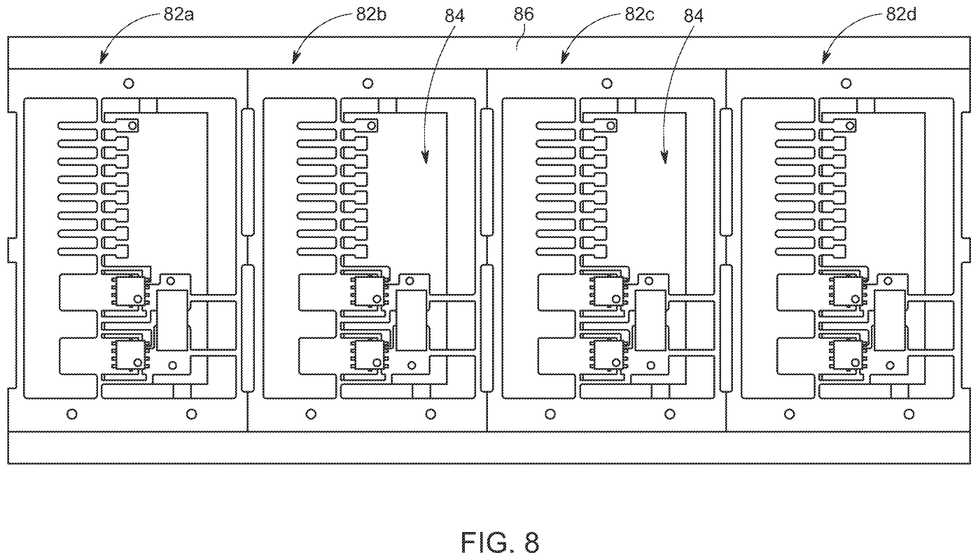

Populated conventional printed circuit boards (PCBs) 84 are provided within a PCB panel 86, FIG. 7, and as shown in FIG. 8, individual subassemblies 82a, 82b, 82c, 82d are laid on top of the PCBs 84. The contacts 28a, 28b, 28c, 28d, 32, 34, 36, 38, 40, 42, 44, 46 of each subassembly 82a, 82b, 82c, 82d are then electrically coupled to the traces on the PCBs 84, by, for example, one or more of solder, fasteners, such as a self-tapping screws, wire or ribbon bond, and the like. Other means for coupling may also be provided.

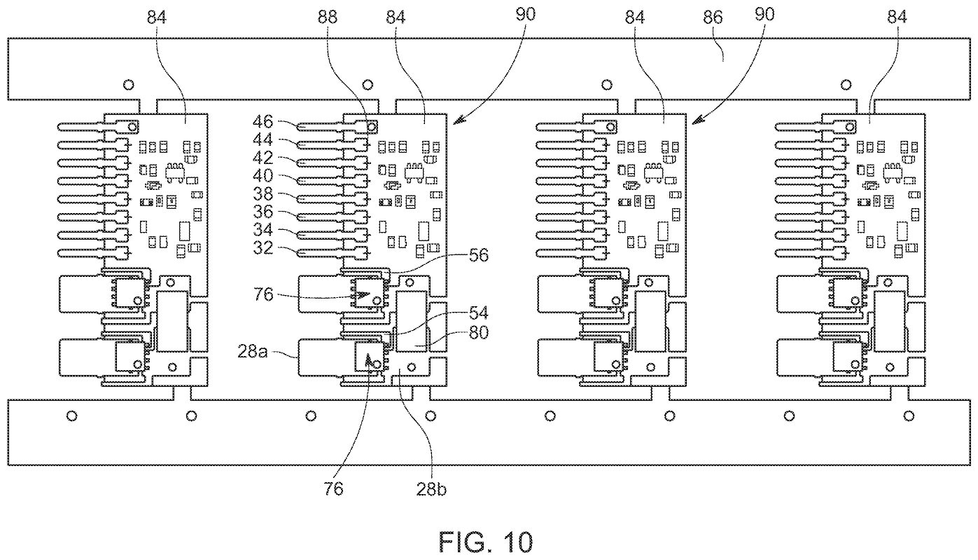

Next, as shown in FIG. 10, the lead frame section 26 and the fingers 48, 50, 52 of each subassembly 82a, 82b, 82c, 82d are removed to leave only the contacts 28a, 28b, 32, 34, 36, 38, 40, 42, 44, 46, 54 and the electronic component 76 (and contacts 28c, 28d, second circuit board contact 56, second electronic component 76, shunt 80, if provided) electrically coupled to each PCB 84, thereby forming individual assemblies 90. Each individual assembly 90 is then removed from the PCB panel 86.

Finally, as shown in FIG. 1, each individual assembly 90 is overmolded with molding compound 92 to create a small solid-state switch. Low pressure molding compound may be used.

The step shown in FIG. 7 can be performed at any time prior to the step shown in FIG. 8.

In an embodiment, circuit board contact 54 (and circuit board contact 56) are eliminated and the signal terminal 74 of the electronic component 76 is directly electrically coupled to the PCB 84.

The first method of manufacturing shown in FIGS. 1-10 creates a sandwich construction of the high-power electronics device 20 having the following layers: a first, bottom layer formed of molding compound 92, a second layer on top of the first layer formed of the PCB 84, a third layer on top of the second layer formed of contacts 28a, 28b, 32, 34, 36, 38, 40, 42, 44, 46, 54 (and contacts 28c, 28d, second circuit board contact 56, if provided), a fourth layer on top of the third layer formed of electronic component 76 (and second electronic component 76, shunt 80, if provided), and a fifth layer on top of the fourth layer formed of molding compound 92. The fifth layer also is on top of the portions of the second layer that are not covered by the third layer. The contacts 28a, 32, 34, 36, 38, 40, 42, 44, 46 extend outward from the molding compound 92 for connection to another electrical device (not shown).

If the embodiment with the two FETs 76 is provided, the contacts form pins. One pin may be a current sense pin, a pin may be a fault detection pin (which is used to shut the device 20 down if a fault is detected), a pin may be an enable pin (which turns current on/off), a pin may be ground, a pin may be configured to connect to a battery (power source), and a pin is configured to connect to the load (the item being driven). In an embodiment, one FET 76 is connected to the battery pin, while the other FET 76 is connected to the load pin, and the shunt 80 is connected to each of the battery and load pins. Thus, the device 20 essentially forms a smart solid-state relay.

Attention is invited to the second method of manufacturing shown in FIGS. 1, 2, and 11-16 which is performed by the following steps.

The stamping 22 is formed as shown in FIG. 2 and the specifics are not repeated herein.

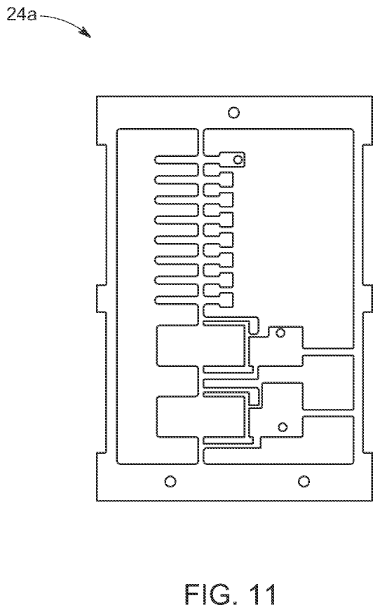

Thereafter, the contact subassemblies 24a, 24b, 24c, 24d are singulated to form individual subassemblies, see FIG. 11. In this embodiment, the electronic component 76 (and second electronic component 76, shunt 80, if provided) are not assembled onto the stamping 22 prior to singulation.

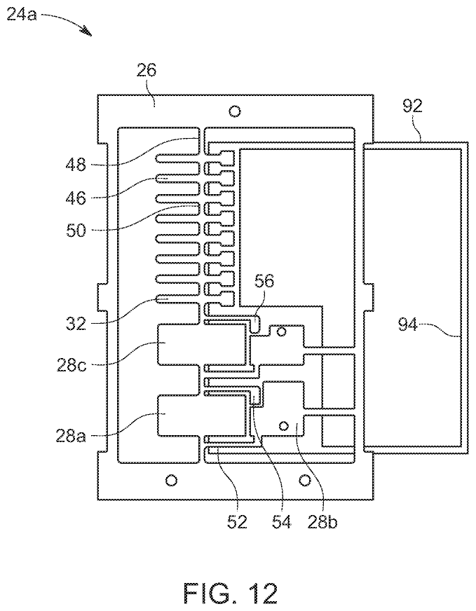

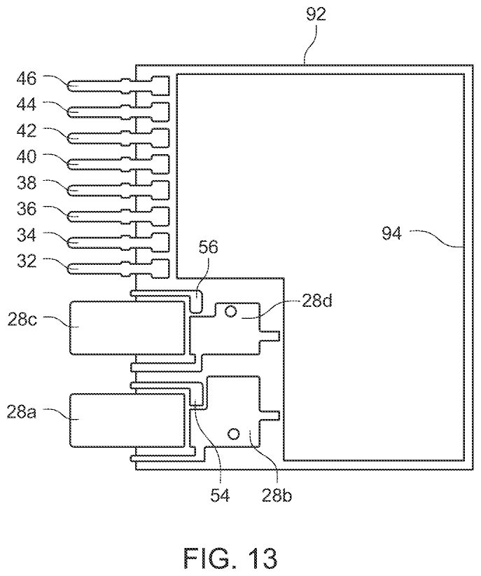

As shown in FIG. 12, the contact subassemblies 24a, 24b, 24c, 24d are insert molded into a dielectric carrier 92. Next, as shown in FIG. 13, the lead frame section 26 and the fingers 48, 50, 52 of each contact subassembly 24a, 24b, 24c, 24d are removed to leave only the contacts 28a, 28b, 32, 34, 36, 38, 40, 42, 44, 46, 54 (and contacts 28c, 28d, second circuit board contact 56, if provided) on the carrier 92.

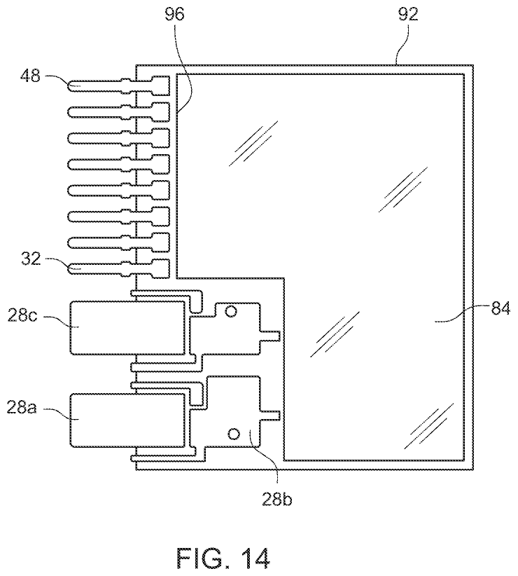

Thereafter, the PCB 84 is laid on top of the carrier 92, or inserted through an opening 94 in the carrier 92, such that an edge 96 of the PCB 84 is proximate to the contacts 28a, 28b, 32, 34, 36, 38, 40, 42, 44, 46, 54 (and contact 56 if provided), see FIG. 14. If the PCB 84 is laid on top of the carrier 92, the PCB 84 may partially lay on top of at least some of the contacts. The PCB 84 is coupled to the carrier 92 to maintain its position on the carrier 92. In some embodiments, the PCB 84 is coupled to the carrier 92 by heat staking.

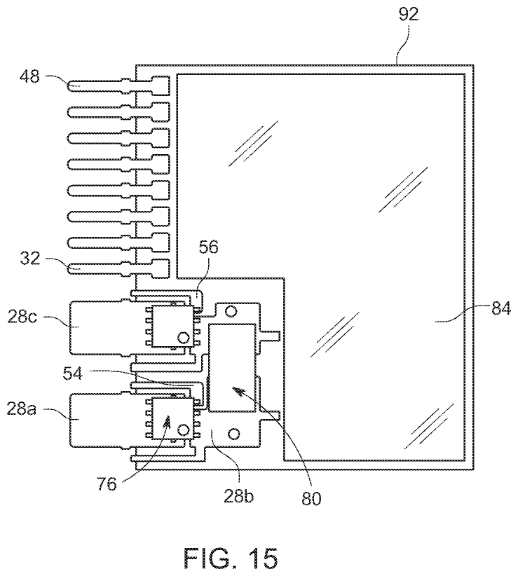

As shown in FIG. 15, the electronic component 76 (and second electronic component 76, shunt 80, if provided) is electrically coupled to the contacts 28a, 28b, 32, 34, 36, 38, 40, 42, 44, 46, 54 (and contact 56 if provided). As shown described above, the signal terminal 74 of the electronic component 76 is electrically coupled, for example by solder, wire or ribbon bond, and the like, to the circuit board contact 54, and the remaining contacts 78 of the electronic component 76 are electrically coupled, for example by solder, wire or ribbon bond, and the like, to the first and second mounting portions 68a, 68b. The electronic component 76 straddles the space 70 between the first and second mounting portions 68a, 68b. Further, the electronic component mounting contacts 28c, 28d and the second circuit board contact 56 are formed as part of the stamping 22, and a second electronic component 76, such as a FET, is electrically coupled in the same manner. This configuration protects the resulting switch from being switched from the battery voltage being reversed. If reverse battery protection is not required, the second electronic component 76, the mounting contacts 28c, 28d and the second circuit board contact 56 would not be necessary, but minor modifications would be required to complete the circuit, e.g., the addition of a zero Ohm resistor or strap, as would be understood by one of ordinary skill in the art. A shunt 80, see FIG. 5, may also be electrically coupled between the second electronic component mounting contacts 28b, 28d to allow for measurement of current flow.

Alternatively, the step shown in FIG. 15 can be performed before the step shown in FIG. 14.

The contacts 28a, 28b, 32, 34, 36, 38, 40, 42, 44, 46, 54 (and contacts 28c, 28d, second circuit board contact 56, if provided) are then electrically coupled to the PCB 84 by, for example, one or more of solder, fasteners, such as a self-tapping screws, wire or ribbon bond, and the like. Other means for coupling may also be provided.

In an embodiment, circuit board contact 54 (and circuit board contact 56, if provided) are eliminated and the signal terminal 74 of the electronic component 76 is directly electrically coupled to the PCB 84.

Finally, as shown in FIG. 1, the carrier 92, PCB 84 and contacts 28a, 28b, 32, 34, 36, 38, 40, 42, 44, 46, 54 (and contacts 28c, 28d, second circuit board contact 56, if provided) are overmolded with molding compound 92 to create a small solid-state switch. Low pressure molding compound may be used.

The second method of manufacturing shown in FIGS. 1, 2, and 11-16 creates a sandwich construction of the high-power electronics device 20 having the following layers: a first, bottom layer formed of molding compound 92, a second layer on top of the first layer formed of the carrier 92, a third layer on top of the second layer formed of the PCB 84, a fourth layer on top of the third layer formed of contacts 28a, 28b, 32, 34, 36, 38, 40, 42, 44, 46, 54 (and contacts 28c, 28d, second circuit board contact 56, if provided), a fifth layer on top of the fourth layer formed of electronic component 76 (and second electronic component 76, shunt 80, if provided), and a sixth layer on top of the fifth layer formed of molding compound 92. The sixth layer also is on top of the portions of the second and third layers that are not covered by the fourth layer. The contacts 28a, 32, 34, 36, 38, 40, 42, 44, 46 extend outward from the molding compound 92 for connection to another electrical device (not shown).

This second embodiment recognizes that solid-state devices suffer from low junction temperatures of the integrated circuits used in them. Many of these devices use FETs and Insulated-Gate Bipolar Transistors (IGBTs) which generate their own heat while operating. This self-generating heat, plus the high temperatures provided in their environment, require thermal management to transfer the heat away from the FETs so the junction temperature is not reached. Current solutions use bare-dies with intimate thermal contact to heat sinks to eliminate heat. This second embodiment solders a packaged FET/IC on thick thermally conductive contact terminal blades to transfer the heat out of the device 20. The PCB 84 may be coupled to the packaged IC terminal using a wire or ribbon bond, and the PCB 84 may be coupled to the signal terminal 74 using a wire or ribbon bond. Manufacturing of the aforementioned solid-state device is described and illustrated below.

While particular embodiments are illustrated and described with respect to the drawings, it is envisioned that those skilled in the art may devise various modifications without departing from the spirit and scope of the appended claims. It will therefore be appreciated that the scope of the disclosure and the appended claims is not limited to the specific embodiments illustrated in and discussed with respect to the drawings and that modifications and other embodiments are intended to be included within the scope of the disclosure and the appended drawings. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the disclosure and the appended claims. Further, the foregoing descriptions describe methods that recite the performance of a number of steps. Unless stated to the contrary, one or more steps within a method may not be required, one or more steps may be performed in a different order than as described, and one or more steps may be formed substantially contemporaneously. Finally, the drawings are not necessarily drawn to scale.

The disclosure provided herein describes features in terms of preferred and exemplary embodiments thereof. Numerous other embodiments, modifications and variations within the scope and spirit of the appended claims will occur to persons of ordinary skill in the art from a review of this disclosure.

We claim:

1. A method of forming a high-power electronics device comprising:
forming a stamping out of a sheet of thick conductive material, the stamping including a lead frame portion and at least first and second electronic component mounting contacts coupled to the lead frame portion by fingers; and
attaching an electronic component to the first and second electronic component mounting contacts to form an assembly, the electronic component having a plurality of terminals, wherein one of the plurality of terminals of the electronic component is not attached to the first and second electronic component mounting contacts.

2. The method as defined in claim 1, wherein the sheet is formed of copper.

3. The method as defined in claim 1, wherein the sheet has a thickness of about 100 microns to about 3,000 microns.

4. The method as defined in claim 3, wherein the sheet has a thickness of about 500 microns to about 800 microns.

5. The method as defined in claim 1, wherein the electronic component is a field effect transistor.

6. The method as defined in claim 1, further comprising:
mounting the assembly to a printed circuit board; and
coupling the contacts with the printed circuit board.

7. The method as defined in claim 6, wherein the contacts are coupled with the printed circuit board by one or more of solder, fasteners and wire or ribbon bond.

8. The method as defined in claim 6, wherein the printed circuit board is mounted onto a fixture prior to coupling with the contacts.

9. The method as defined in claim 6, wherein the printed circuit board is proximate to the contacts.

10. The method as defined in claim 6, wherein the printed circuit board partially lays on top of the contacts.

11. The method as defined in claim 6, further comprising coupling the one of the plurality of terminals of the electronic component to the printed circuit board.

12. The method as defined in claim 11, wherein the one of the plurality of terminals of the electronic component is coupled with the printed circuit board by one of solder and wire or ribbon bond.

13. The method as defined in claim 11, further comprising
removing the lead frame portion and fingers after the assembly is mounted to the printed circuit board to form a second assembly; and
overmolding the second assembly.

14. The method as defined in claim 1, wherein prior to attaching the electronic component to the first and second electronic component mounting contacts, the method further comprises:
insert molding a dielectric carrier to the stamping; and
thereafter removing the lead frame portion and fingers.

15. The method as defined in claim 14, further comprising:
mounting a printed circuit board to the carrier; and
coupling the contacts with the printed circuit board.

16. The method as defined in claim 15, wherein the contacts are coupled with the printed circuit board by one or more of solder, fasteners and wire or ribbon bond.

17. The method as defined in claim 15, further comprising coupling the one of the plurality of terminals of the electronic component to the printed circuit board.

18. The method as defined in claim 17, wherein the one of the plurality of terminals of the electronic component is coupled with the printed circuit board by one of solder and wire or ribbon bond.

19. The method as defined in claim 17, further comprising coupling the contacts with the printed circuit board.

20. A high-power electronics device comprising:
a first layer of molding compound;
a second layer on top of the first layer comprising a printed circuit board;
a third layer on top of the second layer formed of electrically conductive contacts;
a fourth layer on top of the third layer formed of at least one electronic component; and
a fifth layer on top of the fourth layer formed of molding compound.

21. The high-power electronics device of claim 20, further comprising a sixth layer between the first and second layers, the sixth layer comprising a dielectric carrier.
